(19) United States
(12) Patent Application Publication
(10) Pub. No.: US 2006/0152137 A1
(43) Pub. Date: Jul. 13, 2006

(54) Electrically controllable light-emitting device and its electrical connection means

(75) Inventors: Fabien Beteille, Revel (FR); Gregoire Mathey, Chateauneuf Sur Loire (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: SAINT-GOBAIN GLASS FRANCE, Courbevoie (FR)

(21) Appl. No.: 10/530,062

(22) PCT Filed: Oct. 1, 2003
(86) PCT No.: PCT/FR03/02869

§ 371 Date: Dec. 9, 2005

(30) Foreign Application Priority Data
Oct. 9, 2002 (FR) 02/12519

(51) Int. Cl. H05B 33/08

(52) U.S. Cl. 313/503; 313/500

(57) ABSTRACT

Electrically controllable device, in particular electrically controllable system, having variable optical and/or energy properties or electroluminescent device, comprising at least one carrier substrate (1) carrying an electroactive multilayer stack (3) that is placed between an electrode called the “lower” electrode and an electrode called the “upper” electrode, each electrode comprising at least one electrically conducting layer (2) in electrical connection with at least one current bus, characterized in that at least one current bus is in electrical connection with at least one current lead suitable for converting electrical energy into light and distributing it within the electroactive multilayer stack (3).

The subject of the present invention is an electrically controllable device of the glazing type with variable optical properties, or an electroluminescent device.

There is in fact presently a growing demand for electroluminescent glazing for converting electrical energy into light.

So-called electroluminescent systems generally comprise, in a known manner, at least one layer of an organic or inorganic electroluminescent material sandwiched between two suitable electrodes.

It is customary to place electroluminescent systems into several categories according to whether they are of organic type, commonly called OLED (Organic Light-Emitting Diode) or PLED (Polymer Light-Emitting Diode) systems, or of inorganic type, and in this case usually called TFEL (Thin Film Electroluminescent) systems when the functional layer(s) are thin, or screen-printed systems when the functions layer(s) are thick.

It is thus possible to define several families according to the type of electroluminescent material:

that in which the organic electroluminescent material of the thin layer is formed from evaporated molecules (OLEDs) such as, for example, the AlQ₃ (aluminum tris(8-hydroxyquinoline)) complex, DPVBi (4,4′-(diphenylvinylene biphenyl)), DMQA (dimethyl quinacridone) or DCM (4-dicyanomethylene)-2methyl-6-(4-dimethylaminostyryl)-4H-pyran). In this case, additional layers that promote the transporting of electrical carriers (holes and electrons) are joined to each of the faces of the thin layer, these additional layers being called HTL (Hole Transporting Layer) and ETL (Electron Transporting Layer) respectively. In addition, to improve the injection of holes into the HTL layer, the latter is joined to a layer called HIL (Hole Injection Layer) formed, for example, from copper or zinc phthalocyanine;

that in which the organic electroluminescent material of the thin layer is formed from polymers (pLEDs) such as, for example, PPV (poly(para-phenylene vinylene)), PPP (poly(para-phenylene)), DO-PPP (poly(2-decyloxy-1,4-phenylene)), MEH-PPV (poly[2-(2′-ethylhexyloxy)-5-methoxy-1,4-phenylene vinylene)]), CN-PPV (poly[2,5-bis(hexyloxy)-1,4-phenylene-(1-cyanovinylene)]) or PDAF (poly(dialkylfluorene)) polymers, the polymer layer also being joined to a layer that promotes the injection of holes (HIL) formed, for example, from PEDT/PSS (poly(3,4-ethylene-dioxythiophene)/poly(4-styrene sulfonate));

that in which the inorganic electroluminescent material is formed from a thin layer, for example of sulfides such as Mn:ZnS or Ce:SrS, or of oxides such as Mn:Zn₂SiO₄, Mn:Zn₂GeO₄ or Mn:Zn₂Ge₂O₄. In this case, an insulating layer formed from a dielectric, for example Si₃N₄, BaTiO₃ or Al₂O₃/TiO₂, is joined to each of the faces of the thin electroluminescent layer; and

that in which the inorganic electroluminescent material is formed from a thick layer of a phosphor, such as for example Mn:ZnS or Cu:ZnS, this layer being joined to an insulating layer made of a dielectric, for example BaTiO₃, these layers generally being produced by screen printing.

Whatever the type of electroluminescent system—organic or inorganic, thin film or thick film—the multilayer stack, comprising in particular the electroluminescent layer, is joined to two electrodes (a cathode and an anode in the case of organic systems).

Given that electroluminescent systems convert electrical energy directly into light (in particular in the visible range), it is necessary for at least one of the electrodes to be transparent. In general, this is the anode, which is made of ITO (Indium Tin Oxide), fluorine-doped tin dioxide (F:SnO₂) or aluminum-doped zinc oxide (Al:ZnO).

On the other hand, in the case of the cathode, the nature of the material constituting the latter is differentiated according to the type of electroluminescent system. In the case of OLEDs and pLEDs, it is general practice to have a cathode made of an electropositive metal (Al, Mg, Ca, Li etc.) optionally preceded by a thin film of an insulating material, such as LiF or an alloy of these metals, and in the case of inorganic systems (TFEL and thick films), the cathode is generally made of aluminum.

It should also be pointed out that there is a difference as regards the nature of the phenomena involved in converting the electrical energy into light.

In the case of organic systems, the electrons are injected from the cathode into the conduction band of the organic material of the electroluminescent layer and the anode extracts electrons from the valency band of the electroluminescent material (injection of holes). Under the influence of an electric field (the supply voltage applied between the two electrodes of the system), the electrons and the holes migrate in opposite directions. Their combination in the electroluminescent material forms an exciton that can undergo radiative deexcitation (photon emission).

In the case of inorganic systems, the phenomenon allowing the conversion of electrical energy into light is fundamentally different. Here, under the action of a high electric field, typically of the order of 1 to 2 MV/cm, electrons trapped at the interface between the insulating layer and the phosphor layer are released and accelerated to reach energies of up to about 3 eV.

These energetic electrons transfer their energy by impact at the centers of the phosphors, which may undergo radiative deexcitation (photon emission).

These two processes for converting electrical energy into light by means of the electroluminescent systems described above have in common the need to be equipped with current leads for supplying the electrodes, which are generally in the form of two electrically conducting layers on either side of the active layer or of the various active layers of the system.

These current leads must ensure both the flow of high currents in the case of organic systems (these require many charge carriers), and high voltages in the case of inorganic systems (creation of a high electric field needed to accelerate the electrons). In addition, it should be pointed out that these current leads must distribute the current uniformly over the entire surface of the functional layer so as to avoid any phenomenon liable to result in the destruction of the functional layer (the layer made of electroluminescent material), for example breakdown or arcing phenomena, so as to uniformly illuminate the entire surface.

The object of the invention is therefore to propose an improved method of connection for electrically controllable systems of the glazing type that were mentioned above. The object of the invention is more particularly to propose a method of connection that is better from the visual standpoint and/or from the electrical standpoint and which, preferably, remains simple and flexible to implement on an industrial scale. The invention relates to all the systems listed above, and more specifically to electroluminescent glazing.

The subject of the invention is firstly a device of the type described above, which comprises at least one carrier substrate carrying an electroactive multilayer stack that is placed between an electrode called the “lower” electrode and an electrode called the “upper” electrode, each electrode comprising at least one electrically conducting layer. Each of the electrodes is in electrical connection with at least one current bus. According to the invention, at least one of the current leads is formed from a plurality of conducting wires placed uniformly on the surface in electrical contact with at least one current bus outside that region of the carrier substrate which is covered by the electroactive multilayer stack.

For the purposes of the invention, the term “lower” electrode is understood to mean the electrode placed closest to the carrier substrate taken as reference, on which at least some of the active layers (all of the active layers in an organic or inorganic electroluminescent system) are deposited. The “upper” electrode is that deposited on the other side in relation to the same reference substrate.

The invention applies to glazing in the widest sense: the carrier substrate is generally rigid and transparent, and of the glass or polymer type, the polymer being such as polycarbonate or polymethylmethacrylate (PMMA). However, the invention includes polymer-based substrates that are flexible or semiflexible.

The device according to the invention may use one or more substrates, made of toughened or laminated glass, or made of plastic (polycarbonate). The substrate(s) may also be curved.

In general, at least one of the electrodes is transparent. One of them may, however, be opaque.

The active system and the upper electrode are protected, especially mechanically, from oxidation and from moisture, generally by another rigid-type substrate, optionally by lamination using one or more sheets of thermoplastic polymer of the EVA (ethylene/vinyl acetate), PVB (polyvinyl butyral) or PU (polyurethane) type.

The invention also includes the protection of the system by a flexible or semiflexible substrate, especially a polymer-based one, optionally including a gas barrier layer.

It is also possible to dispense with a lamination operation, which is carried out hot and optionally under pressure, by substituting conventional thermoplastic interlayer sheet with a double-sided adhesive sheet, self-supported or otherwise, which is commercially available and has the advantage of being very thin.

For the purposes of the invention, and for the sake of brevity, the term “active stack” or “electroactive stack” is understood to mean the active layer or layers of the system, that is to say all of the layers of the system except the layers belonging to the electrodes. The various types of electroluminescent system of the organic or inorganic type were defined above.

Of course, for all these stacks, each of these layers may be formed from a monolayer or from a plurality of superposed layers fulfilling the same function.

Each electrode generally contains an electrically conducting layer or several superposed electrically conducting layers, which will be considered hereafter as a single layer.

Correct electrical supply for the electrically conducting layer generally requires current buses placed along the edges of the layer when the latter is in the form of a rectangle, a square or has a similar parallelogram-type geometrical shape. These current buses are intended to be connected, on one side, to an AC and/or DC power supply, depending on the type of electrically controllable system and, on the other side, to the electrically conducting layers that include current leads intended for distributing the power over the entire surface of the electrically conducting layers.

Usually, these buses are in the form of shims, that is to say opaque metal strips, generally based on copper, the copper often being tinned. Since the stack and the electrically conducting layer in question generally have the same dimensions, this means that 1 or 2 cm of the assembly must be concealed once the system has been completed, in order to conceal that region of the glazing which is provided with the shims. According to the invention, the dimensions of the active stack are practically the dimensions of the electrically controllable surface that is accessible to the user—there is little or no loss of active area, and in any case much less than the loss of area occasioned by the usual practice of placing the shims on the active stack.

Apart from this major advantage, the invention has another benefit: the way in which the shims are positioned ensures that there will be no risk of the active stack being “injured”. There is no local overthickness in the glazing due to the presence of the shims in the essential region, that in which the active layers of the system are present. Finally, the power supply for these leads thus remote from the sensitive part of the system may be facilitated, as may be the actual placing of said leads.

The aim of the present patent application is firstly to describe a preferred embodiment of the “lower” electrode of the system.

The lower electrode may comprise an electrically conducting layer that covers at least one carrier substrate region not covered by the active stack. The benefit of this configuration is that firstly it is easy to obtain—it is possible to deposit the conducting layer for example on the entire surface of the substrate. This is in fact the case when the electrically conducting layer is placed on glass in the actual glass manufacturing line, especially by pyrolysis on the ribbon of float glass.

The rest of the layers of the system can then be deposited on the glass once it has been cut to the desired dimensions, using a temporary masking system.

The other benefit is that those regions of the substrate which are covered only by the lower electrically conducting layer will be able to be used for positioning the peripheral current buses and the current leads according to the invention.

An example of an electrically conducting layer is a layer based on a doped metal oxide, especially tin-doped indium oxide called ITO or fluorine-doped tin oxide F:SnO₂, or aluminum-doped zinc oxide Al:ZnO for example, optionally deposited on a prelayer of the silicon oxide, oxycarbide or oxynitride type, having an optical function and/or an alkali metal barrier function when the substrate is made of glass.

We have seen that the lower electrically conducting layer has regions that are not covered by the active stack. Some of these will be used for the ad hoc placement of the current buses. These current buses are intended to be in contact with the current leads that allow uniform distribution of the power needed for the functional layer in order to convert this power into light.

The aim of the present patent application is now to describe preferred configurations of the “upper” electrode.

This “upper” electrode comprises an electrically conducting layer joined, on one side, to current buses that are similar in their embodiments and their functions to those used in the “lower” electrode and, on the other side, to current leads.

The current leads are either conducting wires, if the electroluminescent active layer is sufficiently conducting, or an array of wires running onto or into the layer forming the electrode, this electrode being metallic or of the TCO (Transparent Conductive Oxide) type made of ITO, F:SnO₂ or Al:ZnO, or a conducting layer by itself.

The conducting wires are metal wires, for example made of tungsten (or copper), optionally covered with a surface coating (of carbon or a colored oxide for example), with a diameter of between 10 and 100 μm and preferably between 20 and 50 μm, whether these are straight or corrugated, that are deposited on a lamination interlayer, for example based on PU, using a technique known in the field of wire-based heated windshields, for example that described in patents EP-785 700, EP-553 025, EP-506 521 and EP-496 669.

One of these known techniques consists in using a heated press roll that presses the wire against the surface of the polymer sheet, this press roll being supplied with wire from a feed spool via a wire-guide device.

As regards the upper conducting layer, this generally has dimensions that are less than or equal to that of the underlying active layers of the active stack and can therefore be deposited after the active layers on the same deposition line (for example by cathode sputtering). It is unnecessary for the two conducting layers of the system to be transparent, or even translucent. One of the faces may be of the mirror type.

In the case of organic systems, the cathode generally is formed from an electropositive metal (Al, Mg, Ca, Li, etc.) optionally preceded by a thin layer of an insulating material such as LiF, or from an alloy of these metals.

To make these systems transparent, one possibility is to use, as cathode, an ITO layer preceded by a thin layer (a few nm) of copper or zinc phthalocyanine, or by a thin layer (less than 10 nm) of metal or alloy. Another possibility for producing transparent organic systems is to use, as cathode, p-doped transparent semiconductors such as, for example, those of the CuAlO₂, CuSr₂O₂ or N:ZnO type.

As regards inorganic systems, the upper layer is generally formed from layers of doped oxide of the type comprising ITO, F:SnO₂ or doped ZnO, for example doped with Al, Ga, etc., or from a metal layer, made of aluminum for example, or of the silver type, said layer being optionally joined to one or more protective layers that may also be conducting (Ni, Cr, NiCr, etc.) and to one or more protective and/or optically active layers, made of a dielectric (metal oxide, Si₃N₄, BaTiO₃).

By using this type of additional conducting network, the present invention will retain these important advantages, but it will also make use of another possibility afforded by its presence, namely: thanks to these wires or these strips, it will be possible to shift the current buses away from the surface covered by the upper conducting layer, by electrically connecting them not to this layer but to the ends of these wires or strips, which are configured so as to “project beyond” the surface of the conducting layer.

In its preferred embodiment, the conducting network comprises a plurality of metal wires placed on the surface of a sheet of thermoplastic-type polymer: this sheet with the wires encrusted into its surface may be affixed to the upper conducting layer in order to ensure their physical contact/electrical connection. The thermoplastic sheet may be used for laminating the first glass-type carrier substrate to another glass and thus provide a safety function by structural assembly.

Advantageously, the wires/strips are placed essentially parallel to one another (the wires may be straight or corrugated), preferably in a direction essentially parallel to the length or to the width of the upper conducting layer. The ends of these wires extend beyond the substrate region covered by the upper conducting layer on two of its opposed sides, especially by at least 0.5 mm, for example from 3 to 10 mm. They may be made of copper, tungsten, tungsten with a colored surface (oxide, graphite, etc.), or else made of an iron-based alloy of the iron-nickel type.

It is judicious to avoid making the ends of these wires come into electrical contact with the lower conducting layer. It is therefore preferable for the ends that extend beyond the upper conducting layer to be in contact with the lower conducting layer only in the deactivated regions of the latter.

Alternatively or in addition, to avoid any short circuit with the lower conducting layer, the ends of the wires may be electrically isolated from the latter (at the point where they are liable to be in contact with its active region) by interposing one or more strips of insulating material, for example polymer-based material.

It should be noted that it is possible, alternatively or in addition, to use the same type of conductor network for the “lower” electrode.

The aim of the present patent application is now to describe various types of current bus and their arrangements in the system.

As regards the upper electrode, in one variant, the ends of the wires/strips of the abovementioned conductor network (forming the current leads) may be electrically connected to current buses in the form of flexible strips made of insulating polymer that are covered on one of their faces with conductive coatings. This type of lead is sometimes called a PFC (Flexible Printed Circuit) or FLC (Flat Laminated Cable) and has already been used in a variety of electrical/electronic systems. Its flexibility, the various configurations that it can adopt and the fact that the current bus is electrically insulated on one of its faces make its use very attractive in the present case.

According to another variant, the ends of these wires are in electrical contact with two deactivated regions of the lower conducting layer, and these two deactivated regions are in electrical connection with the current buses that are intended for the upper electrode. For convenience, these may be conducting clips that grip the carrier substrate in the aforementioned regions. This is a novel solution whereby the lower electrode is used to ensure electrical connection of the upper electrode.

As regards the current buses for the lower electrode, these may be electrically connected along two of their opposed edges in active regions not covered by the active stack. These buses may be the abovementioned clips.

It is also possible to bring together the current buses for the lower and upper electrodes in the form of the abovementioned flexible strips. Thus there may be two substantially identical strips, each having a support made of a flexible and electrically insulating polymer and being approximately in the form of L or a U (of course, there may be many other conceivable configurations depending on the geometrical shape of the carrier substrate and of the layers with which it is provided). On one of the sides of this L or this U, there will be a conductive coating on one face. On the other side of the L or of one of the other sides of the U, there will be a conductive coating on the opposite face from the previous one. This overall current bus system is therefore formed from two of these Ls (four sides in the case of a U) on a plastic support. When joined together, they provide two conducting strips on one face in the case of one of the electrodes and two conducting strips on their opposite face for the other electrode. This is a compact system, easy to put into place. Near the junction between the two edges of each L, there will be an electrical connector electrically connected to the conductive coatings of the buses.

It is also possible to achieve further compactness by replacing these two Ls by a complete frame: in this case, a strip of insulating polymer of approximately rectangular shape is used, a conductive coating along two of its opposed edges on one face and on its other two opposed edges on the other face. There is then preferably more than one single external electrical connector instead of two. The frame may be in one piece, or made of several parts that are joined together during assembly.

The current buses for the lower and/or upper electrodes may also be in the form of conventional shims, for example in the form of metal strips of the optionally tinned copper type.

The current buses for the lower and/or upper electrodes may also be in the form of a conducting wire (or several conducting wires joined together) similar to the network of wires forming the current leads associated with the polymer film in conjunction with the electrically conducting layers of the electroluminescent system.

These wires may be made of copper, tungsten or tungsten with a colored surface (graphite, oxide, etc.) and may be similar to those used for forming the abovementioned conductor network. They may have a diameter ranging from 10 to 600 μm. This type of wire is in fact sufficient for the electrodes to be satisfactorily supplied electrically and are remarkably discrete—it may be unnecessary to mask them when assembling the device.

The configuration of the current buses is very adaptable. Approximately rectangular active systems have been described in greater detail above, but these may come in many different geometrical shapes, depending in particular on the geometrical shape of their carrier substrate, namely circle, square, semicircle, oval, any polygon, diamond, trapezoid, square, any parallelogram, etc. In these situations, the current buses are no longer necessarily, for each electrode to be supplied, “pairs” of current buses facing each other. Thus, they may, for example, be current buses that go right around the conducting layer (or at the very least go along a good part of its perimeter). This is quite achievable when the current bus is a single conducting wire. It may even be a point current bus, especially when the device is small in size.

The glazing according to the invention may include additional functionalities: for example, it may include an infrared-reflecting coating, as described in patent EP-825 478. It may also include a hydrophilic, antireflection or hydrophobic coating, or a photocatalytic coating having antifouling properties, comprising titanium oxide in anatase form, as described in patent WO 00/03290.

The invention will be explained in detail with nonlimiting illustrative examples with the aid of the following figures:

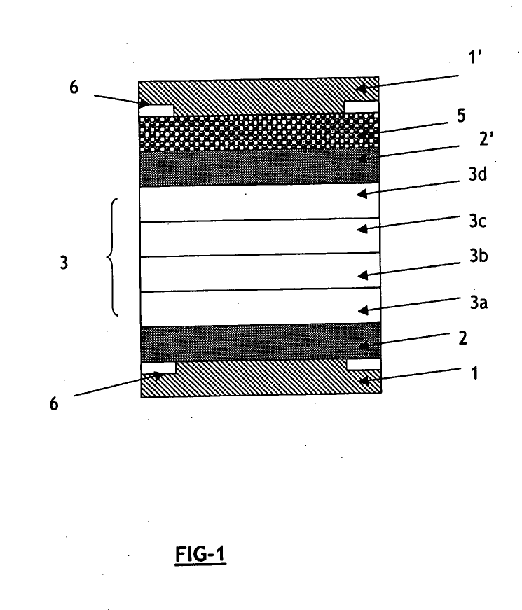

FIGS. 1, 3, 4 and 5 illustrate various multilayer stacks of electroluminescent systems; and

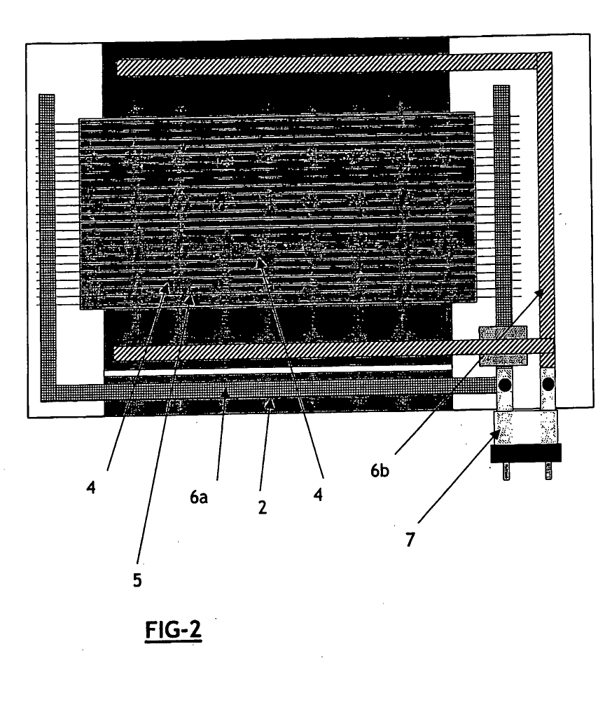

FIGS. 2, 6 and 7 illustrate various electrical connection methods for the electroluminescent systems shown in FIGS. 1, 3, 4 and 5.

All the figures are schematic so as to make them easy to examine, and the various elements that they show are not necessary drawn to scale.

They all relate to an electroluminescent glazing unit, in a laminated structure comprising two glass panes, in a configuration suitable for example to be used as a window for automobiles or for buildings.

All the figures show a glass pane 1 provided with a lower conducting layer 2, with an active stack 3 surmounted by an upper conducting layer 2′, with a network of conducting wires 4 placed above the lower conducting layer 2 and encrusted in the surface of a sheet 5 of EVA (ethylene/vinyl acetate), PU (polyurethane) or PVB (polyvinyl butyral). The glazing unit also has a second glass pane 1′. The two glass panes 1, 1′ and the sheet of EVA, PU or PVB are joined together by a known laminating or calendering technique, with heating and optionally pressure.

The lower conducting layer 2 is a layer based on a doped metal oxide, especially tin-doped indium oxide called ITO or fluorine-doped tin oxide F:SnO₂ or aluminum-doped zinc oxide Al:ZnO for example, said layer being optionally deposited on a prelayer of the silicon oxide, oxycarbide or oxynitride type, having an optical function and/or an alkali metal barrier function when the substrate is made of glass.

Thus, the conducting layer forming the “lower” electrode may be a bilayer formed from an SiOC first layer with a thickness of between 10 and 150 nm, especially 20 to 70 nm and preferably 50 nm surmounted by an F:SnO₂ second layer of 100 to 1000 nm, especially 200 to 600 nm and preferably about 400 nm (the two layers preferably being deposited in succession by CVD on the float glass before cutting).

As a variant the lower electrode is formed from an ITO or F:SnO₂ monolayer with a thickness of 100 to 1000 nm and especially about 100 to 300 nm.

Alternatively, this may be a bilayer formed from a first layer based on SiO₂ doped with Al or B having a thickness of between 10 and 150 nm, especially 10 to 70 nm and preferably approximately 20 nm, surmounted by an ITO second layer of 100 to 1000 nm, preferably about 100 to 300 nm (the two layers preferably being deposited in succession, under vacuum, by optionally hot, magnetically-enhanced reactive sputtering in the presence of oxygen).

The conducting wires 4 shown in the figures are mutually parallel straight copper wires deposited on the EVA or PU sheet 5 by a technique known in the field of wire-type heated windshields, for example the technique described in patents EP-785 700, EP-553 025, EP-506 521 and EP-496 669. Schematically, a heated press roll is used, which presses the wire into the surface of the polymer sheet, the press roll being fed with wire from a feed spool via a wire-guide device.

The EVA sheet 5 has a thickness of about 0.8 mm.

The two glass panes 1, 1′ are made of standard clear soda-lime silica glass, each with a thickness of about 2 mm.

### EXAMPLE 1

This is the configuration shown in FIG. 1:

the lower conducting layer 2 covers the entire surface of the glass;

the active system 3 that is made up, as follows, of a multilayer stack comprising: at least one HIL layer 3a based on an unsaturated, especially polyunsaturated, heterocyclic compound, such as copper or zinc phthalocyanine, with a thickness of between 3 and 15 nm and preferably 5 nm; an HTL layer 3b, approximately 10 to 150 nm, especially 20 to 100 nm and preferably 50 nm in thickness, of N,N′-diphenyl-N,N′-bis(3-methylphenyl)-1,1′-biphenyl-4,4′-diamine (TPD) or N,N′-bis(1-naphthyl)-N,N′-diphenyl-1,1′-biphenyl-4,4′-diamine (α-NPD); a layer 3c, of approximately 50 to 500 nm and preferably 100 nm thickness, of evaporated molecules of the complex AlQ₃ (aluminumtris(8-hydroxyquinoline)) optionally doped with a few percent of rubrene, DCM or quinacridone; and an ETL layer 3d, 10 to 300 nm and especially 20 to 100 nm and preferably 50 nm in thickness, of 2-(4′-biphenyl)-5-(4″-tert-butylphenyl)-1,3,4-oxadiazole(t-Bu-PBD) or of 3-(4′-biphenyl)-4-phenyl-5-(4″-tert-butylphenyl)-1,3,4-triazole (TAZ); all these layers are deposited by evaporation; and

the upper conducting layer 2′ is based on an electropositive metal (Al, Mg, Ca, Li, etc.) or an alloy of said metal, optionally preceded by a thin dielectric layer of LiF; the upper conducting layer 2′ and the dielectric layer are deposited by evaporation.

The active system 3 and the upper conducting layer 2′ also cover a rectangular region of the substrate, possibly having dimensions smaller than the region covered by the lower conducting layer. These two rectangular regions are centered one with respect to the other.

FIG. 2 shows mutually symmetrical current buses 6, namely two conducting strips 6a, 6b of approximately U shape, optionally coated with an insulating polymer. On the shortest side of the conducting strip 6a, the conductive coating (the insulating polymer has been removed at this point in order to make this part of the strip conducting) is turned toward the wires 4. On the longest side of the conducting strip 6b, the conductive coating (at this point the insulating polymer has been removed in order to make this part of the strip conducting) is turned toward the lower conducting layer 2.

The conductive coatings of the strip 6a are in electrical contact with the wires 4 and therefore, via these wires 4, supply the upper electrode and the current leads with power. The end of these wires, outside the surface covered by the stack 3, is in contact only with the insulating polymer support for the current leads: thus, any risk of a short circuit between these wires and the lower electrode 2 is avoided.

The conductive coatings of the strip 6b are in contact with those regions of the lower conducting layer 2 that are active and not covered by the stack 3: they allow power to be supplied to the lower conducting layer 2 via the current leads. For each of the current buses, there is an electrical connector 7 placed approximately in the angle of the U of the current lead, with suitable electrical couplers for each of the conductive coatings.

### EXAMPLE 2

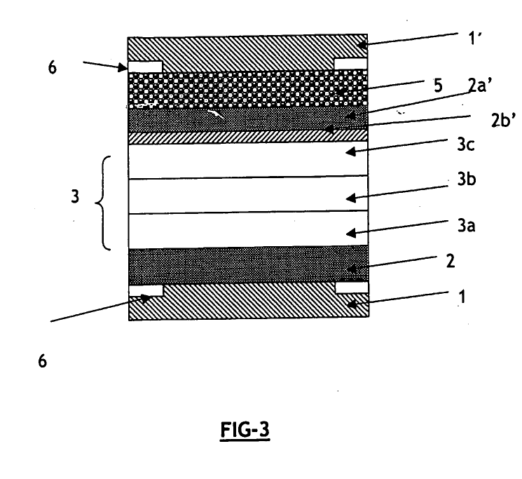

This configuration is quite similar to that of example 1 and is illustrated in FIG. 3.

The differences lie in the nature of the upper electrode, which allows a transparent system to be produced:

the lower conducting layer 2 covers the entire surface of the glass;

the active system 3 that is made up, as follows, of a multilayer stack comprising: at least one HIL layer 3a based on an unsaturated, especially polyunsaturated, heterocyclic compound, such as copper or zinc phthalocyanine, with a thickness of between 3 and 15 nm and preferably 5 nm; an HTL layer 3b, approximately 10 to 150 nm, especially 20 to 100 nm and preferably 50 nm in thickness, of N,N′-bis(1-naphthyl)-N,N′-diphenyl-1,1′-biphenyl-4,4′-diamine (α-NPD); a layer 3c, of 10 to 300 nm and especially 20 to 100 nm and preferably 50 nm thickness, of AlQ₃ emitting molecules. The good electron transport properties of the AlQ₃ layer make it possible to dispense with an additional ETL layer; all these layers are deposited by an evaporation technique; and

the upper conducting layer 2′ comprises an ITO layer 2′a 55 nm in thickness deposited by a sputtering technique, preceded by a thin layer 2′b, of 5 nm thickness, of copper phthalocyanine or a layer 2′b of 10 nm thickness of an Mg/Al (30:1) alloy, these layers being deposited by evaporation.

### EXAMPLE 3

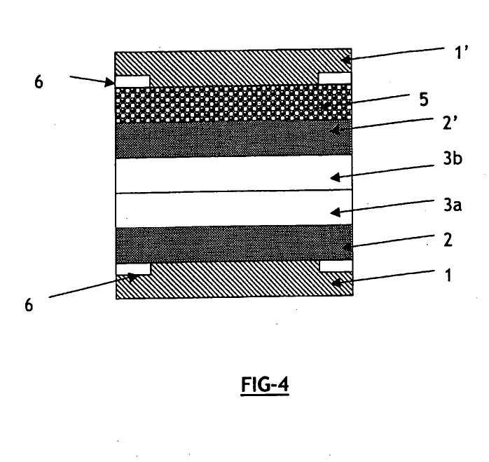

This is the configuration shown in FIG. 4—it is quite similar to that of example 1.

The difference from example 1 lies in the nature of the active system 3. In this example, there is a multilayer stack comprising an HIL layer 3a made of PEDT/PSS, of 10 to 300 nm, especially 20 to 100 nm and preferably 50 nm thickness, and a polymer layer 3b based on PPV, PPP, DO-PPP, MEH-PPV or CN-PPV, with a thickness of 50 to 500 nm, especially 75 to 300 nm and preferably 100 nm. These layers are produced using a spin coating technique.

### EXAMPLE 4

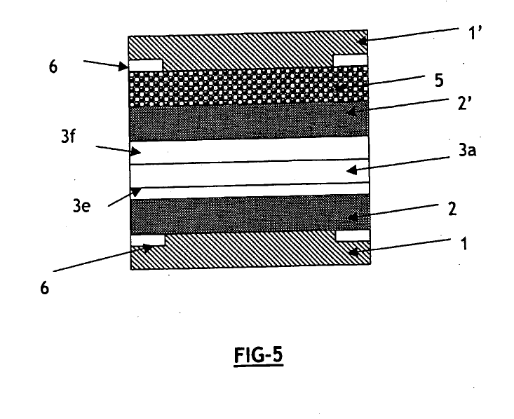

This configuration is quite similar to that of example 1 or example 3, and is illustrated in FIG. 5.

The differences lie in the nature of the active system and the nature of the upper electrode.

The active system 3 is formed by a multilayer stack comprising at least one layer 3a based on an active material 100 to 1000 nm, especially 300 to 700 nm and preferably about 500 nm in thickness, such as for example Mn:ZnS, Ce:SrS, Mn:Zn₂SiO₄, Mn:Zn₂GeO₂ or Mn:ZnGa₂O₄; this layer 3a, obtained by evaporation or sputtering, is joined on either side to an insulating layer 3e and 3f made of a dielectric (Si₃N₄, BaTiO₃ or Al₂O₃/TiO₂) of 50 to 300 nm, especially 100 to 200 nm and preferably about 150 nm thickness; the layers 3e and 3f are produced by sputtering and are not necessarily of the same nature and of the same thickness.

The upper conducting layer 2′, 50 to 300 nm, especially 75 to 200 nm and preferably about 100 nm in thickness, is based on aluminum.

### EXAMPLE 5

This configuration is quite similar to that of example 4.

The differences lie in the nature of the upper electrode 2′, which allows a transparent system to be produced.

The active system 3 is formed by a multilayer stack, the layers being deposited by evaporation or sputtering, comprising at least one layer based on active material, 100 to 1000 nm, especially 300 to 700 nm and preferably about 500 mm in thickness, such as for example Mn:ZnS, Ce:SrS, Mn:Zn₂SiO₄, Mn:Zn₂GeO₂ or Mn:ZnGa₂O₄, this layer being joined on either side to an insulating layer obtained by sputtering, made of a dielectric (Si₃N₄, BaTiO₃ or Al₂O₃/TiO₂) 50 to 300 nm, especially 100 to 200 nm and preferably about 150 nm in thickness.

The upper conducting layer 2′, of 50 to 300 nm, especially 100 to 250 nm and preferably about 200 nm thickness, is based on ITO, this layer being produced by sputtering.

### EXAMPLE 6

This configuration is quite similar to that of example 4.

The differences lie in the thickness of the layers, which are called “thick” and generally obtained by a screen-printing technique.

The active system 3 is formed by a multilayer stack comprising a layer based on active material 10 to 100 μm, especially 15 to 50 μm and preferably about 30 μm in thickness, such as for example Mn:ZnS or Cu:ZnS, this layer being joined an insulating layer made of a dielectric (BaTiO₃) 10 to 100 μm, especially 15 to 50 μm and preferably about 25 μm in thickness.

The upper conducting layer 2′, of 10 to 100 μm, especially 15 to 50 μm and preferably about 7 μm thickness, is based on aluminum, silver or carbon.

These six examples therefore have in common of activating or deactivating the electroluminescent glazing on both its opposed faces, in regions that overlap the region covered only by the lower conducting layer, and the layer covered both with this layer and with the active stack 3.

As a variant, it is possible to use, as current buses, conducting clips for supplying the lower conducting layer 2 and conducting clips for supplying the upper electrode 2′.

These clips are commercial products, that can grip the glass rendered conductive, and are available in various sizes.

As regards the lower conducting layer 2, these clips are fitted onto and cover the edge of the glass, so as to be electrically connected to the edges of the layer 2 that are active. They are shorter than the length separating the two lines of incision of the layer.

As regards the upper electrode 2′, the clips clip onto the glass pane 1′, thus establishing an electrical connection with the deactivated regions of the layer 2. These deactivated regions, isolated from the rest of the layer, will make electrical connection with the ends of the wires 4, and thus allow the upper conducting layer 2′ to be supplied. Thus, the deactivated regions of the lower electrode 2 are used to be able to supply power to the upper electrode via the conducting wires 4.

### EXAMPLE 7

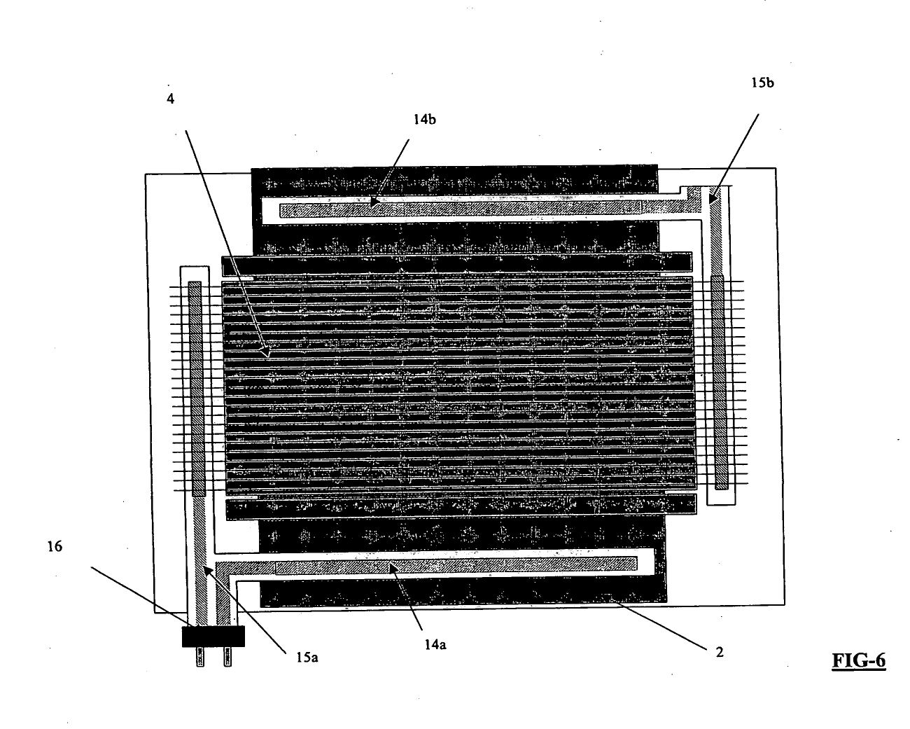

According to yet another variant, shown in FIG. 6, the current buses are in fact standard shims, in the form of strips of tinned copper about 3 mm in width:

strips 14a, 14b for supplying the lower conducting layer 2; and

strips 15a, 15b for supplying the upper conducting layer via the end of the wires 4 of the conductor network (in fact two superposed shims sandwiching the end of the wires 4).

These strips are electrically connected to a single electrical connector 16. To avoid a short circuit between the strips 14a and 15a, a sheet of electrically insulating polymer material is interposed, for example, between the two strips.

### EXAMPLE 8

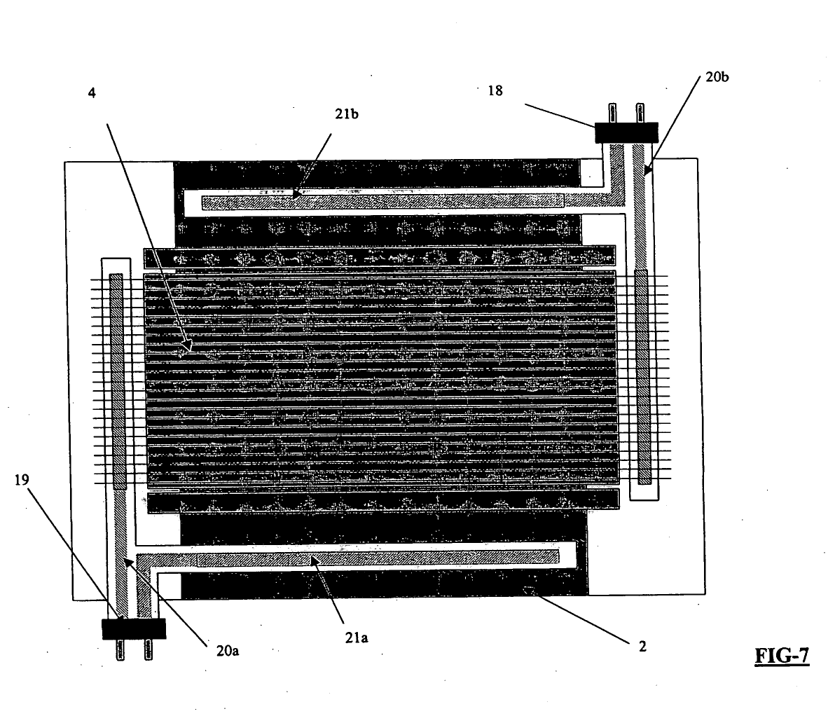

This is another alternative embodiment of the current buses (FIG. 7): here, the same standard tinned-copper shims as those of example 7 are used. In this example 8, there are thus two electrical connectors 18 and 19—each is electrically connected to two superposed shims 20a, 20b intended to supply the upper conducting layer via the end of the wires 4 and to a shim 21a, 21b intended to supply the lower conducting layer 2. The shims are connected to the connectors by soldering.

In conclusion, the invention is susceptible to many alternative ways of electrically supplying electroluminescent-type systems. It is possible to envision using a network of conducting wires or of screen-printed conducting strips for the lower electrode, instead of or in addition to the wires used in the examples for the upper electrode. Various current buses can be used, including standard shims or strips of flexible polymer that are provided with conductive coatings. Particularly discrete current buses can also be used, such as single conducting wires or even point current leads.

Depending on the type of assembly, it is possible to end up with only two electrical connectors, and even with just a single electrical connector, which makes it very easy to supply the device with power.

It is possible to make electroluminescent glazing devices of very varied geometry, even though the examples, for the sake of simplicity, describe active stacks of rectangular surface.

These electroluminescent glazing units are applicable for illumination both in the building field (comfort, safety or decorative lighting) on walls, ceilings or handrails, and in the automobile field on roofs, side windows, rear windows, and as a head-up display device.

The invention lies in the fact of moving the visible electrical buses away to the periphery of the active layers that define the actual active region of the glazing unit, while still allowing these current buses to uniformly dissipate and distribute the consequent electrical power to the current leads, these being almost invisible in the lower and/or upper electrodes.

1. An electrically controllable device comprising variable optical and/or energy properties or an electroluminescent device, comprising at least one carrier substrate (1,1′) carrying an electroactive multilayer stack (3) that is placed between an electrode called the “lower” electrode and an electrode called the “upper” electrode, each electrode comprising at least one electrically conducting layer (2,2′) in electrical connection with at least one current bus, wherein at least one of the current buses is in electrical connection with at least one current lead comprising either conducting wires (4) or a network of wires running over or within the layer (2,2′) forming the electrode suitable for distributing, over the surface of at least one of the conducting layers (2,2′), electrical energy so as to convert the electrical energy into light uniformly within the electroactive multilayer stack (3).

2. The device as claimed in claim 1, wherein the conducting wires (4) are metal wires, for example made of tungsten (or copper), optionally covered with a surface coating, with a diameter of between 10 and 100 μm and preferably between 20 and 50 μm, which are straight or corrugated, and deposited on a sheet of thermoplastic (5).

3. The device as claimed in claim 1, wherein the “lower” electrode comprises an electrically conducting layer (2) covering a region of the carrier substrate, especially one that is essentiallly rectangular, the lower electrode (2) being based on a doped metal oxide, especially tin-doped indium oxide called ITO or fluorine-doped tin oxide F:SnO₂, or aluminum-doped zinc oxide Al:ZnO for example, optionally deposited on a prelayer of the silicon oxide, oxycarbide or oxynitride type, having an optical function and/or an alkali metal barrier function when the substrate is made of glass.

4. The device as claimed in claim 1, wherein the conducting layer (2) forming the “lower” electrode may be a bilayer formed from an SiOC first layer of between 10 and 150 nm, especially 20 to 70 nm and preferably 50 nm thickness, surmounted by an F:SnO₂ second layer of between 100 and 1000 nm, especially 200 to 600 nm and preferably 400 nm thickness.

5. The device as claimed in claim 4, wherein the device comprises a bilayer formed from a first layer based on SiO₂ doped with a little metal of the Al or B type, about 20 nm in thickness, surmounted by an ITO second layer of about 100 to 300 nm thickness.

6. The device as claimed in claim 4, wherein the device comprises a layer formed from ITO about 100 to 300 nm in thickness.

7. The device as claimed in claim 1, wherein the active system (3) comprises a multilayer stack comprising: at least one HIL layer (3a) based on an unsaturated, especially polyunsaturated, heterocyclic compound such as a copper or zinc phthalocyanine or a PEDT/PSS compound 5 nm in thickness; an HTL layer (3b), 50 nm in thickness, of N,N′-diphenyl-N,N′bis(3-methylphenyl)-1,1′-biphenyl 4,4′diamine (TPD) or N,N′-bis-(1-naphthyl)-N,N′-diphenyl-1,1′-biphenyl-4,4′-diamine ((α-NPD); a layer (3c), 100 nm in thickness, of evaporated molecules of the complex AlQ₃ (aluminum tris(8-hydroxyquinoline)) optionally doped with a few percent of rubrene, DCM or quinacridone; and an ETL layer (3d), 50 nm in thickness, of 2-(4′-biphenyl)-5-(4″-tert-butylphenyl)-1,3,4-oxadiazole (t-Bu-PBD) or 3-(4′-biphenyl)-4-phenyl-5-(4″-tert-butylphenyl)-1,2,4-triazole (TAZ).

8. The device as claimed in claim 1, wherein the active system (3) comprises a mutilayer stack comprising: at least one HIL layer (3a) made of PEDT/PSS 50 nm in thickness; and a layer (3b) of polymers based on PPV, PPP, DO-PPP, MEH-PPV or CN-PPV, 100 nm in thickness.

9. The device as claimed in claim 1, wherein the active system (3) comprises a multilayer stack comprising: at least one layer (3a) based on an active material 500 nm in thickness, such as for example sulfides like Mn:ZnS, Ce:SrS, or Mn:Zn₂SiO₄, Mn:Zn₂GeO₂ or Mn:ZnGa₂O₄, this layer (3a) being joined on either side to insulating layers (3e, 3f) made of a dielectric (Si₃N₄, Al₂O₃/TiO₂ or BaTiO₃) with a thickness of 150 nm.

10. The device as claimed in claim 1, wherein the electrically conducting layer (2′) forming the upper electrode is based on a metal or metal alloy of aluminum.

11. The device as claimed in claim 1, wherein the electrically conducting layer forming the upper electrode (2¹) is based on an electropositive metal (Al, Mg, Ca, etc.) or an alloy of said metals.

12. The device as claimed in claim 1, wherein at least one of the two electrodes, preferably the “upper” electrode, comprises an electrically conducting layer joined to a network (4) of conducting wires/conducting strips.

13. The device as claimed in claim 12, wherein the conducting network (4) comprises a plurality of essentially metallic wires placed on the surface of a sheet (5) of polymer, especially of the thermoplastic type.

14. The device as claimed in claim 12, wherein the wires/strips (4) are placed essentially parallel to one another, preferably in an orientation essentially parallel to the length or the width of the electrically conducting layer (2′) of the “upper” electrode, the ends of said wire/strips extending beyond the substrate region covered by said electrically conducting layer on two of its opposed edges, especially by at least 0.5 mm.

15. The device as claimed in claim 12 wherein the ends of the wires/strips (4) joined to the electrically conducting layer (2) of the “lower” electrode are electrically connected to current buses in the form of flexible strips (6a, 6b) made of insulating polymer, these being covered on one of their faces with a conductive coating.

16. The device as claimed in claim 15, wherein said current buses are in the form of conducting clips that grip the carrier substrate (1,1′).

17. The device as claimed in claim 15, wherein the set of current buses for the “lower” and “upper” electrodes are brought together in the form of a strip of approximately rectangular shape, formed from an electrically insulating and flexible polymer support, with, on two opposed edges, a conductive coating on one face and, on its other two edges, a conductive coating on the face on the opposite side from the previous one, preferably with a single external electrical connector.

18. The device as claimed in claim 1 wherein at least one of the current buses is in the form of a shim (14a, 14b, 15a, 15b), especially a metal strip, or in the form of one or more conducting wires, or in the form of a point lead made of conducting material.

19. The device as claimed in claim 1 wherein the electroactive stack (3) covers a carrier substrate region which is a polygon, a rectangle, a diamond, a trapezoid, a square, a circle, a semicircle, an oval or any parallelogram.

20. The device as claimed in claim 1 wherein the device it makes up an electroluminescent system.

21. The device as claimed in claim 20, wherein the electroluminescent system is transparent.

22. The device as claimed in claim 20, wherein the device it is an electroluminescent glazing unit, especially of laminated structure.

23. The device as claimed in claim 20, wherein the electroluminescent glazing unit comprises at least one flat glass pane and/or at least one curved glass pane.

24. The device as claimed in claim 20 wherein the device also includes at least one of the following coatings: an infrared-reflecting coating, a hydrophilic coating, a hydrophobic coating, a photocatalytic coating with anti-fouling properties, an anti-reflection coating, an electromagnetic shielding coating.

25. The device as claimed in claim 20 wherein the carrier substrate (1) is rigid, semirigid or flexible.

26. A method for glazing automobiles or buildings comprising applying the device as claimed in claim 1 to an automobile or building.
